(19) United States
(12) Patent Application Publication
(10) Pub. No.: US 2024/0063192 A1
(43) Pub. Date: Feb. 22, 2024

(54) DISPLAY PANEL AND DISPLAY DEVICE

(71) Applicant: Wuhan Tianma Microelectronics Co., Ltd., Wuhan (CN)

(72) Inventor: Dandan Peng, Wuhan (CN)

(73) Assignee: Wuhan Tianma Microelectronics Co., Ltd., Wuhan (CN)

(21) Appl. No.: 18/385,557

(22) Filed: Oct. 31, 2023

(30) Foreign Application Priority Data
Oct. 31, 2022 (CN) 202211351448.9

(51) Int. Cl. H01L 25/075; H01L 27/15; H01L 25/16; H01L 33/62

(52) U.S. Cl. CPC H01L 25/0753; H01L 27/156; H01L 25/167; H01L 33/62

(57) ABSTRACT

Provided are a display panel and a display device. The display panel includes a light-transmissive region, a display region at least partially surrounding the light-transmissive region, and a non-light-emitting region located between the light-transmissive region and the display region. In the radial direction of the light-transmissive region, the difference in the size of the non-light-emitting region located around the light-transmissive region is ΔD, where 0 μm≤|ΔD|≤10 μm.

### CROSS-REFERENCE TO RELATED APPLICATION

This application claims priority to Chinese Patent Application No. 202211351448.9 filed Oct. 31, 2022, the disclosure of which is incorporated herein by reference in its entirety.

### TECHNICAL FIELD

The present invention relates to display techniques and, in particular, to a display panel and a display device.

### BACKGROUND

Currently, a light-transmissive hole (that is, AA hole) is disposed in the display region of a display panel to dispose a photosensitive element such as a camera. Thus, it is not necessary to reserve a corresponding space for disposing the photosensitive element in the non-display region of the display panel so that the display panel has a narrow bezel or an extremely narrow bezel, thereby increasing screen-to-body ratio.

However, due to the arrangement manner of pixels, the position of the light-emitting center of each pixel around the AA hole is limited, so the display black edge around the AA hole is not uniform, thereby affecting the overall display effect.

### SUMMARY

The present invention provides a display panel and a display device.

According to one aspect of the present invention, a display panel is provided. The display panel includes a light-transmissive region, a display region at least partially surrounding the light-transmissive region, and a non-light-emitting region located between the light-transmissive region and the display region.

In the radial direction of the light-transmissive region, the difference in the size of the non-light-emitting region located around the light-transmissive region is ΔD, where 0 μm≤|ΔD|≤10 μm.

According to another aspect of the present invention, a display device is provided. The display device includes the preceding display panel.

It is to be understood that the contents described in this part are not intended to identify key or important features of the embodiments of the present invention, and are not intended to limit the scope of the present invention. Other features of the present invention become readily understood through the description hereinafter.

### BRIEF DESCRIPTION OF DRAWINGS

To illustrate technical solutions in embodiments of the present invention more clearly, drawings used in description of the embodiments are briefly described below. Apparently, the drawings described below merely illustrate part of the embodiments of the present invention, and those of ordinary skill in the art may obtain other drawings based on the drawings on the premise that no creative work is done.

FIG. 1 is a diagram illustrating the structure of a display panel in the related art.

FIG. 2 is an enlarged diagram illustrating the structure of region A′ in FIG. 1.

FIG. 3 is a diagram illustrating the structure of a display panel according to embodiments of the present invention.

FIG. 4 is an enlarged diagram illustrating the structure of region A in FIG. 3.

FIG. 5 is a diagram illustrating the structure of another display panel according to embodiments of the present invention.

FIG. 6 is a diagram illustrating the partial structure of a display panel according to embodiments of the present invention.

FIG. 7 is a diagram illustrating the partial structure of another display panel according to embodiments of the present invention.

FIG. 8 is a diagram illustrating the partial structure of another display panel according to embodiments of the present invention.

FIG. 9 is a diagram illustrating the partial structure of another display panel according to embodiments of the present invention.

FIG. 10 is a diagram illustrating the structure of a film layer of a display panel according to embodiments of the present invention.

FIG. 11 is a diagram illustrating the structure of a specific circuit of a pixel according to embodiments of the present invention.

FIG. 12 is a diagram illustrating the partial structure of another display panel according to embodiments of the present invention.

FIG. 13 is a diagram illustrating the partial structure of another display panel according to embodiments of the present invention.

FIG. 14 is a diagram illustrating the partial structure of another display panel according to embodiments of the present invention.

FIG. 15 is a diagram illustrating the partial structure of another display panel according to embodiments of the present invention.

FIG. 16 is a diagram illustrating the partial structure of another display panel according to embodiments of the present invention.

FIG. 17 is a diagram illustrating the partial structure of another display panel according to embodiments of the present invention.

FIG. 18 is a diagram illustrating the partial structure of another display panel according to embodiments of the present invention.

FIG. 19 is a diagram illustrating the structure of a film layer of another display panel according to embodiments of the present invention.

FIG. 20 is a diagram illustrating the structure of a film layer of another display panel according to embodiments of the present invention.

FIG. 21 is a diagram illustrating the structure of a film layer of another display panel according to embodiments of the present invention.

FIG. 22 is a diagram illustrating the structure of driving circuits arranged in an array in a display panel according to embodiments of the present invention.

FIG. 23 is a diagram illustrating the structure of driving circuits arranged in an array in another display panel according to embodiments of the present invention.

FIG. 24 is a diagram illustrating the structure of a display device according to embodiments of the present invention.

### DETAILED DESCRIPTION

The technical solutions in the embodiments of the present invention are described clearly and completely in conjunction with the drawings in the embodiments of the present invention from which the solutions of the present invention are better understood by those skilled in the art. Apparently, the embodiments described below are part, not all, of the embodiments of the present invention. Based on the embodiments of the present invention, all other embodiments obtained by those of ordinary skill in the art on the premise that no creative work is done are within the scope of the present invention.

It is to be noted that the terms “first”, “second” and the like in the description, claims and drawings of the present invention are used to distinguish between similar objects and are not necessarily used to describe a particular order or sequence. It is to be understood that the data used in this way is interchangeable where appropriate so that the embodiments of the present invention described herein may also be implemented in a sequence not illustrated or described herein. In addition, the terms “including”, “having”, or any other variations thereof described herein are intended to encompass a non-exclusive inclusion. For example, a process, method, system, product, or device that includes a series of steps or units may include not only the expressly listed steps or units but also other steps or units that are not expressly listed or are inherent to such a process, method, system, product, or device.

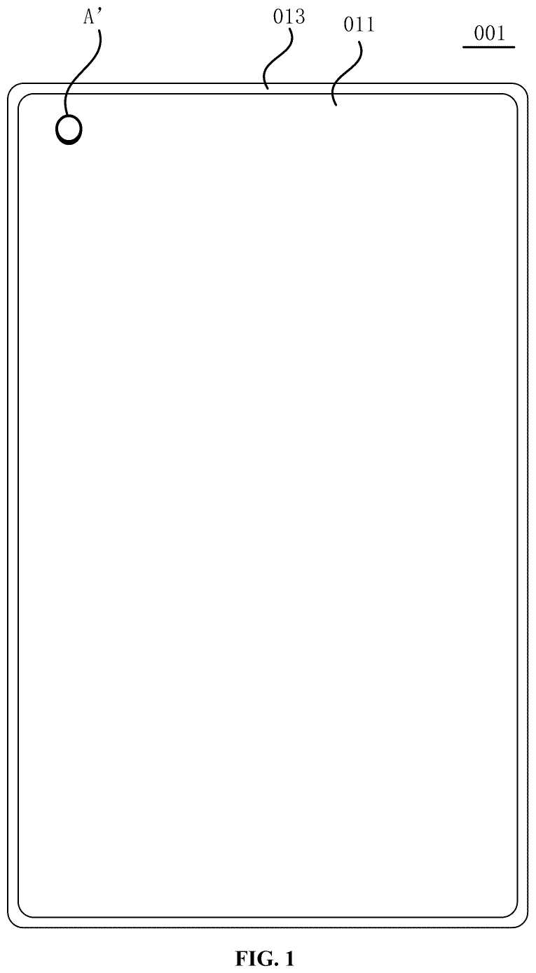

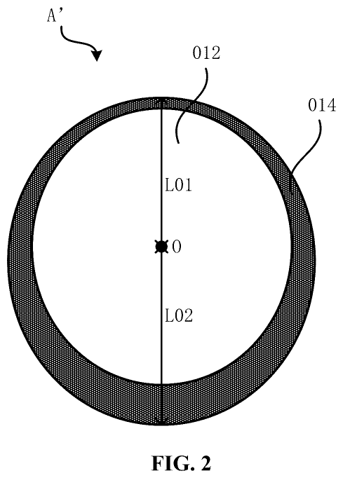

As described in the background, to improve the screen-to-body ratio of the display panel, a light-transmissive region configured to dispose a sensor such as a camera is generally disposed in the display region. FIG. 1 is a diagram illustrating the structure of a display panel in the related art. FIG. 2 is an enlarged diagram illustrating the structure of region A′ in FIG. 1. With reference to FIG. 1 and FIG. 2, a display panel 001 includes a light-transmissive region 012, a display region 011 surrounding the light-transmissive region 012, and a non-display region 013 surrounding the display region 011. The display region 011 generally includes multiple driver circuits arranged in an array and multiple light-emitting elements having different light-emitting colors. The light-emitting elements are electrically connected to the driver circuits so that the driver circuits can drive the light-emitting elements to emit light for display. The light emitted from the light-emitting elements with different light-emitting colors is combined with each other so that the display panel can present a display image with rich colors.

To meet higher requirements of display and light emission, in the case of display and light emission, the arrangement of the light-emitting elements needs to satisfy pixel borrowing or other special design. Thus, the light-emitting elements in the display region 011 are not arranged in an array, but are distributed in the display region according to a certain rule, for example, in a YYG arrangement, a Delta arrangement, and a diamond arrangement which are common at present so that there are no strict rows and columns.

However, since the light-transmissive region 012 located in the display region 011 generally has a regular shape, such as a circle or a rectangle, the distribution of the light-emitting elements around the light-transmissive region 012 is different, so the radiation range of the light emitted from the light-emitting elements around the light-transmissive region 012 is different. Thus, the size of the presented non-light-emitting region 014 around the light-transmissive region 012 is different. For example, the distance L01 between the edge of the non-light-emitting region 014 above the light-transmissive region 012 and the center 0 of the light-transmissive region 012 is significantly less than the distance L02 between the edge of the non-light-emitting region 014 below the light-transmissive region 012 and the center 0 of the light-transmissive region 012. Therefore, when an image is displayed, the presented display black edge around the light-transmissive region 012 is not uniform, thereby affecting the overall display effect.

In some related art, black ink is coated around the position corresponding to a light-transmissive hole on a cover plate to limit the display black edge around the light-transmissive hole by the shading action of the black ink. However, when the cover plate is attached, there is an attachment common difference. When the attachment common difference is consistent with the deviation direction of the non-light-emitting regions around the light-transmissive region, the problem of an ununiform display black edge around the light-transmissive region is further aggravated.

To solve the preceding technical problems, according to the embodiments of the present invention, a non-light-emitting region is disposed between the light-transmissive region and the display region. Moreover, in the radial direction of the light-transmissive region, the range of the difference ΔD in the size of the non-light-emitting region around the light-transmissive region is controlled to be 0 μm≤|ΔD|≤10 μm. Thus, a uniform display black edge is disposed around the light-transmissive region, thereby improving the display effect.

The preceding is the core idea of the present invention. Based on the embodiments of the present invention, all other embodiments obtained by those of ordinary skill in the art are within the scope of the present invention on the premise that no creative work is done. Technical solutions in embodiments of the present invention are described clearly and completely hereinafter in conjunction with the drawings in the embodiments of the present invention.

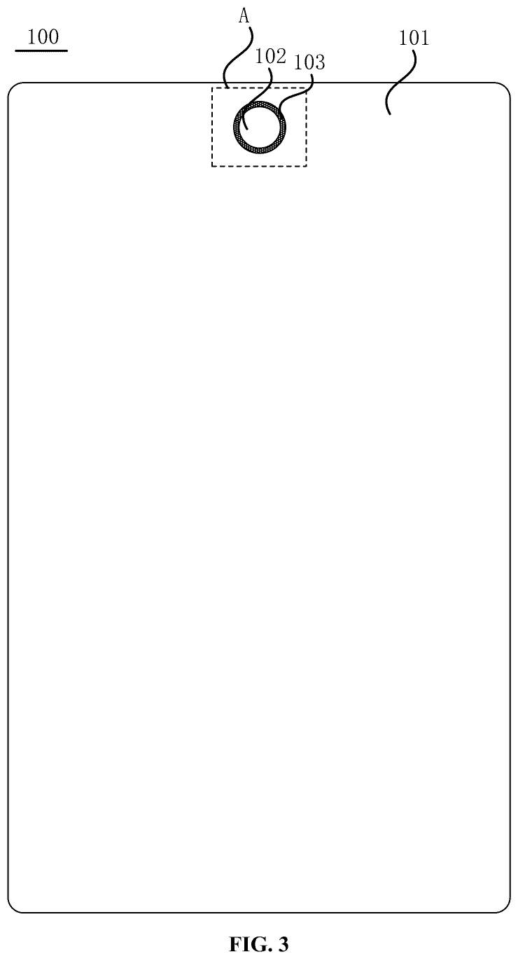

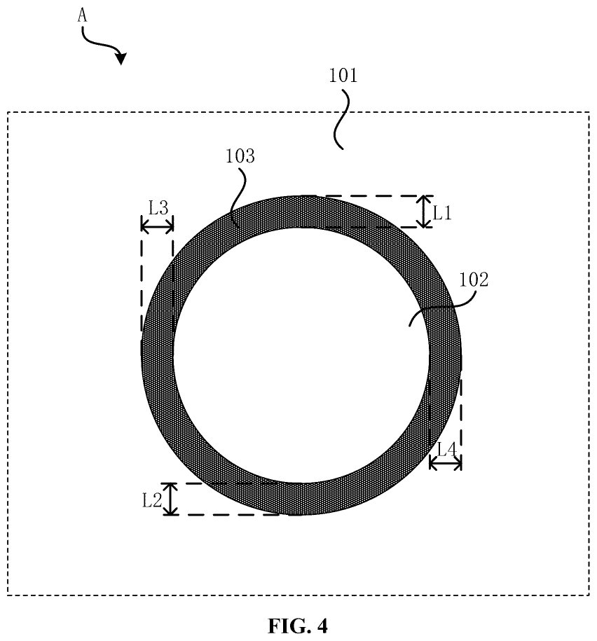

FIG. 3 is a diagram illustrating the structure of a display panel according to the embodiments of the present invention. FIG. 4 is an enlarged diagram illustrating the structure of region A in FIG. 3. With reference to FIG. 3 and FIG. 4, a display panel 100 includes a light-transmissive region 102, a display region 101 at least partially surrounding the light-transmissive region 102, and a non-light-emitting region 103 located between the light-transmissive region 102 and the display region 101. In the radial direction of the light-transmissive region 102, the difference in the size of the non-light-emitting region 103 located around the light-transmissive region 102 is ΔD, where 0 μm≤|ΔD|≤10 μm.

The light-transmissive region 102 may be used for disposing a photosensitive element such as a camera or an infrared sensor. The display region 101 may be provided with a structure such as a pixel for display and light emission. When the display panel performs display and light emission, the pixel may be controlled to perform display and light emission so that the display panel 100 can display a preset image. Limited by the arrangement manner of pixels in the display region, a complete pixel structure may not be disposed in the region around the light-transmissive region 102, so the pixel structure may not be disposed in this region. At the same time, since pixels have a certain radiation range when displaying and emitting light, the light emitted from the pixels around the light-transmissive region 102 cannot completely cover the region around the light-transmissive region 102. Thus, there is a non-light-emitting region 103 between the light-transmissive region 102 and the display region 101. When the display panel 100 displays an image, the non-light-emitting region 103 appears as a display color corresponding to a lower grayscale, that is, the non-light-emitting region 103 can be considered as a display black edge around the light-transmissive region 102. The non-light-emitting region 103 may be a fixed region or may be a region that varies with the display brightness, and the embodiments of the present invention are not specifically limited thereto.

Exemplarily, as shown in FIG. 4, the radial direction of the light-transmissive region 102 is the direction in which the light-transmissive region 102 points to the display region 101. The size of the non-light-emitting region 103 located around the light-transmissive region 102 is the linear distance from the edge of the light-transmissive region 102 to the edge of the side of the non-light-emitting region 103 facing the display region 101 along the radial direction. The size of the non-light-emitting region 103 in each orientation around the light-transmissive region 102 is limited to a certain size range. For example, the size L1 of the non-light-emitting region 103 above the light-transmissive region 102, the size L2 of the non-light-emitting region 103 below the light-transmissive region 102, the size L3 of the non-light-emitting region 103 on the left of the light-transmissive region 102, and the size L4 of the non-light-emitting region 103 on the right of the light-transmissive region 102 may all be in the range of L−5 μm to L+5 μm. In this case, the value range of the difference ΔD (L1−L2, L1−L3, L1−L4, L2−L3, L2−L4, L3−L4) in the size of the non-light-emitting region 103 in different orientations may be 0 μm≤|ΔD|≤10 μm to ensure that the size of the non-light-emitting region 103 in each orientation around the light-transmissive region 102 can be kept uniform. Thus, the display black edge around the light-transmissive region 102 can be kept uniform when the display panel 100 displays an image. In an optional embodiment, the size of the non-light-emitting 103 located in each orientation around the light-transmissive region 102 may be the same, that is, L1=L2=L3=L4. In this case, the difference ΔD in the size of the non-light-emitting region 103 in different orientations is 0 μm.

In the embodiments, the non-light-emitting region is disposed between the light-transmissive region and the display region. Moreover, in the radial direction of the light-transmissive region, the range of the difference ΔD in the size of the non-light-emitting region around the light-transmissive region is controlled to be 0 μm≤|ΔD|≤10 μm. Thus, the size of the non-light-emitting region around the light-transmissive region is kept uniform so that a uniform display black edge is disposed around the light-transmissive region, thereby improving the display effect.

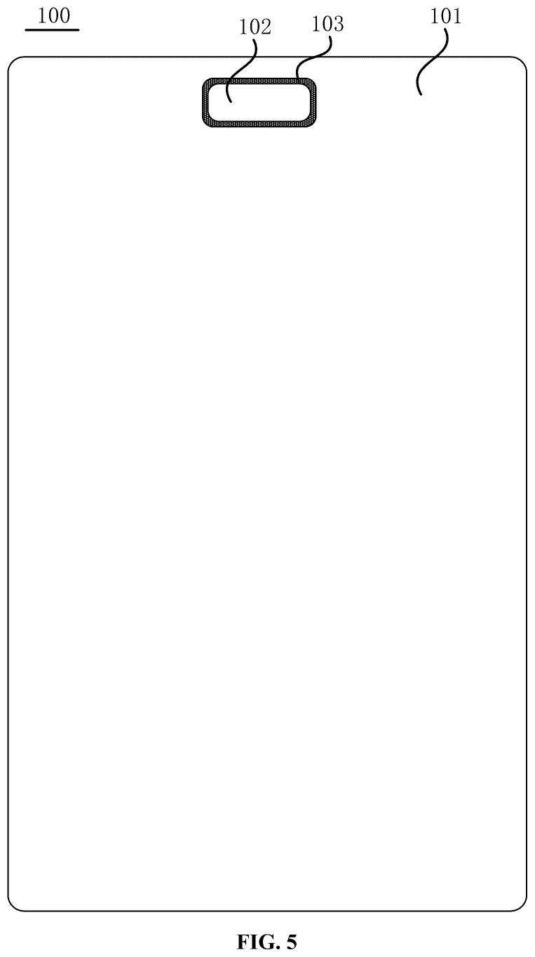

It is to be noted that FIG. 3 is only an example drawing in embodiments of the present invention. FIG. 3 illustrates only that the shape of the light-transmissive region 102 in the display panel 100 is a circle. The shape of the light-transmissive region 102 in the display panel 100 in the embodiments of the present invention may be other shapes. Exemplarily, as shown in FIG. 5, the shape of a light-transmissive region 102 is a rectangle. Alternatively, in other optional embodiment, the shape of the light-transmissive region 100 may also include, but is not limited to, an oval, a trapezoid, or a triangle. For ease of description, in the embodiments of the present invention, the case where the shape of the light-transmissive region is a circle is used as an example for the exemplary description of the technical solutions in the embodiments of the present invention.

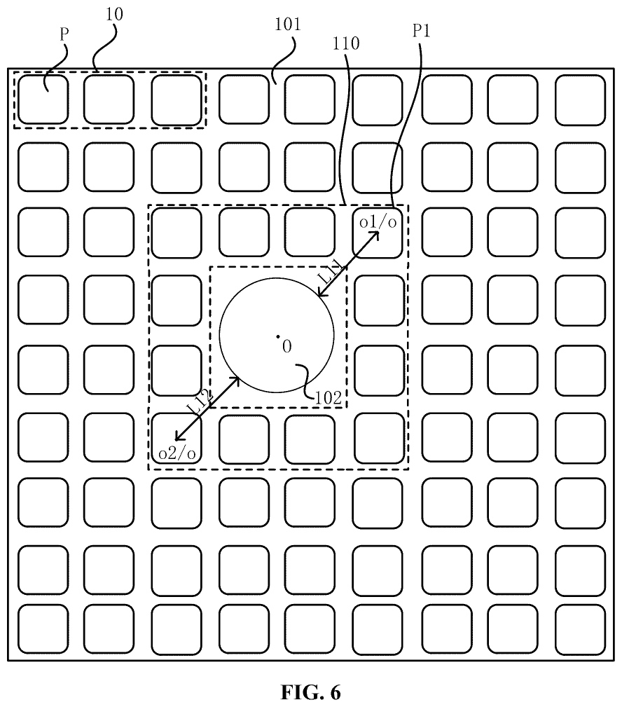

Optionally, FIG. 6 is a diagram illustrating the partial structure of a display panel according to the embodiments of the present invention. As shown in FIG. 6, a display region 101 includes multiple pixel units 10. Each pixel unit 10 includes multiple pixels P of different colors. For example, the pixels P in the same pixel unit 10 may be a red pixel, a green pixel, and a blue pixel, respectively. The light-emitting color of the red pixel is red. The light-emitting color of the green pixel is green. The light-emitting color of the blue pixel is blue. The light emitted from the pixels P of different colors is combined with each other so that the display panel can present a display image with rich colors.

It is to be understood that the preceding is only an example of the color of each pixel P in the same pixel unit 10. The color of the pixels P in the embodiments of the present invention is not limited thereto. For example, the pixels P may include a yellow pixel and/or a white pixel, or the like. This may be designed according to actual requirements, and the embodiments of the present invention are not specifically limited thereto.

With continued reference to FIG. 6, multiple pixels P at least partially surrounding the light-transmissive region 102 form a first pixel group 110. At least part of pixels in the first pixel group 110 are first pixels P1. The difference between shortest distances from light-emitting centers o of the first pixels P1 located around the light-transmissive region 102 and of the same color to the light-transmissive region 102 is M, wherein, 0 μm≤|M|≤10 μm.

The first pixel group 110 may be composed of the pixels P surrounding the light-transmissive region 102 and closest to the light-transmissive region 102, or may be composed of the pixels P in the display region 101 of a certain size surrounding the light-transmissive region 102. The embodiments of the present invention are not specifically limited thereto. In this case, all pixels P in the first pixel group 110 may be the first pixels P1. Alternatively, pixels of only one or two colors in the first pixel group 110 are the first pixels P1. This may be set according to actual requirements, and the embodiments of the present invention are not specifically limited thereto.

It is to be understood that the light-emitting center o of a pixel P may be considered to be the brightest light emission point in the pixel. Generally, the radiation range of the light emitted from the pixel P and the brightness of the emitted light in the radiation range are related to the position of the light-emitting center of the pixel. The radiation range and brightness of the light emitted from the pixels P of different colors are different, and the radiation orientation and brightness of the light emitted from the pixels P of the same color under the same grayscale are the same. Therefore, when the distances between the light-emitting centers o of the pixels P of the same color around the light-transmissive region 102 and the light-transmissive region 102 are the same, the size of the non-light-emitting region around the light-transmissive region 102 can be ensured to be uniform.

Exemplarily, as shown in FIG. 6, the case where the pixels P in the first pixel group 110 include the pixels P surrounding the light-transmissive region 102 and closest to the light-transmissive region 102 is used as an example. The light-emitting centers o of two first pixels P1 of the same color in the first pixel group 110 are o1 and o2 in a one-to-one manner. Of the two first pixels P1, the shortest distance L11 between the light-emitting center o1 of one first pixel P1 and the light-transmissive region 102 is the linear distance between the light-emitting center o1 of the first pixel P1 and the edge of the light-transmissive region 102. Similarly, the shortest distance L12 between the light-emitting center o2 of another first pixel P1 and the light-transmissive region 102 is the linear distance between the light-emitting center o2 of the first pixel P1 and the edge of the light-transmissive region 102. If the distances L11 and L12 between the light-emitting centers o (o1 and o2) of the two first pixels P1 and the edge of the light-transmissive region 102 are kept uniform, when the display grayscale corresponding to the two first pixels P1 is kept uniform, the two first pixels P1 can have the same display brightness, and the distances between the radiation regions of the light emitted from the two first pixels P1 and the edge of the light-transmissive region 102 are consistent. The non-light-emitting region located around the light-transmissive region 102 is the region to which the light emitted from the pixels around the light-transmissive region 102 does not radiate. Therefore, when the distances between the radiation regions of the light emitted from two first pixels P1 and the edge of the light-transmissive region 102 are kept uniform, the size of the non-light-emitting region around the light-transmissive region 102 can be ensured to be uniform.

Thus, the value range of the difference M between the shortest distances from the light-emitting centers o of first pixels P1 located around the light-transmissive region 102 and of the same color to the light-transmissive region 102 is set to be 0 μm≤|M|≤10 μm. In this manner, there is a small difference between the shortest distances from the light-emitting centers of the first pixels P1 located around the light-transmissive region 102 and of the same color to the light-transmissive region 102. That is, the shortest distances from the light-emitting centers of the first pixels P1 located around the light-transmissive region 102 and of the same color to the light-transmissive region 102 are kept uniform. Thus, the human eye does not distinguish the difference in light intensity of light emitted from each pixel around the light-transmissive region 102 to the surrounding of the light-transmissive region 102, that is, the display black edge around the light-transmissive region felt by the human eye is ensured to be uniform.

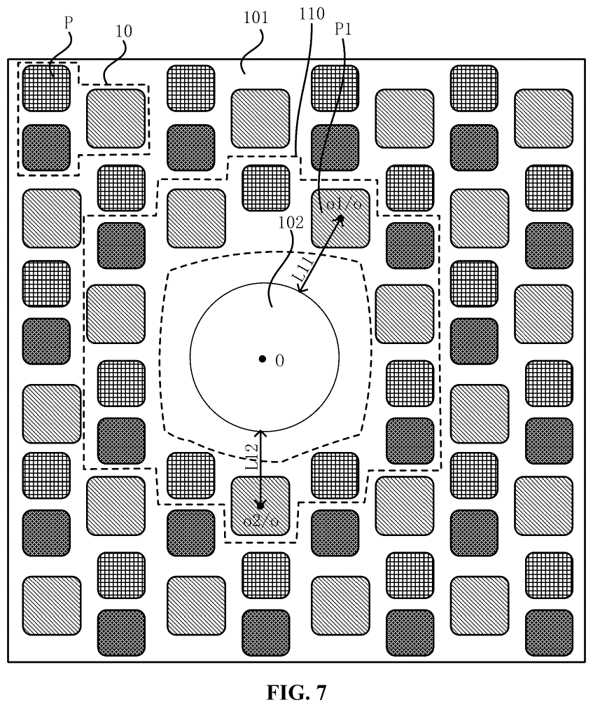

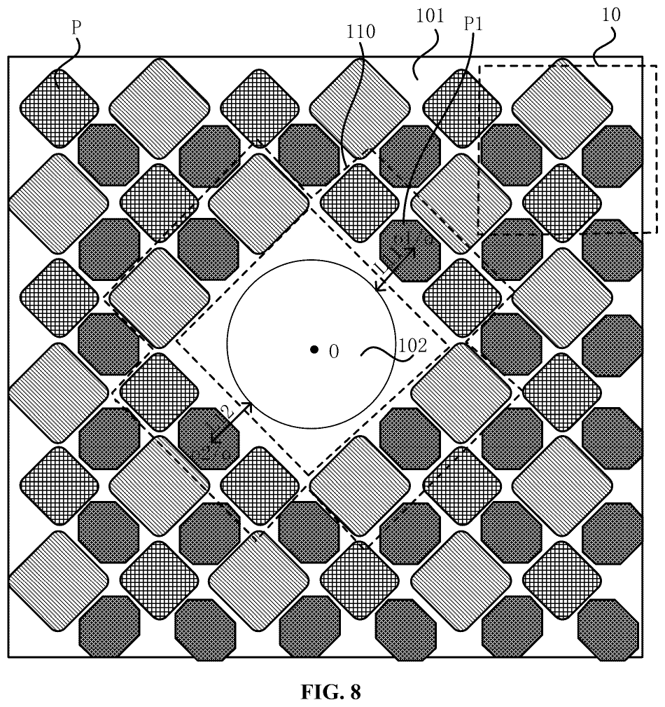

It is to be noted that FIG. 6 only exemplarily shows that the pixels P are arranged in an array in the display region 101. In the embodiments of the present invention, the arrangement manner of the pixels is not limited thereto. As shown in FIG. 7, the pixels P may also be arranged in a YYG arrangement. Alternatively, as shown in FIG. 8, the pixels P may be arranged in a diamond arrangement. On the premise that the core invention points of the embodiments of the present invention can be implemented, the arrangement manner of the pixels in the display region is not specifically limited in the embodiments of the present invention. For ease of description, an example of a diamond arrangement is taken hereinafter for exemplarily describing technical solutions in the embodiments of the present invention.

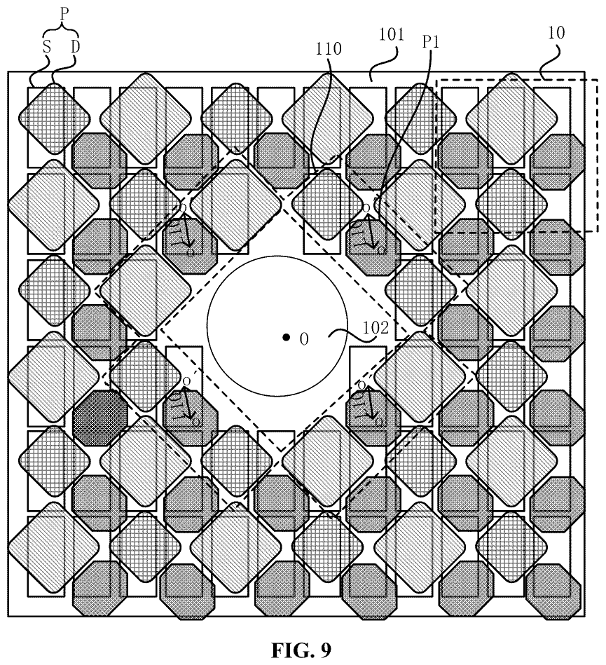

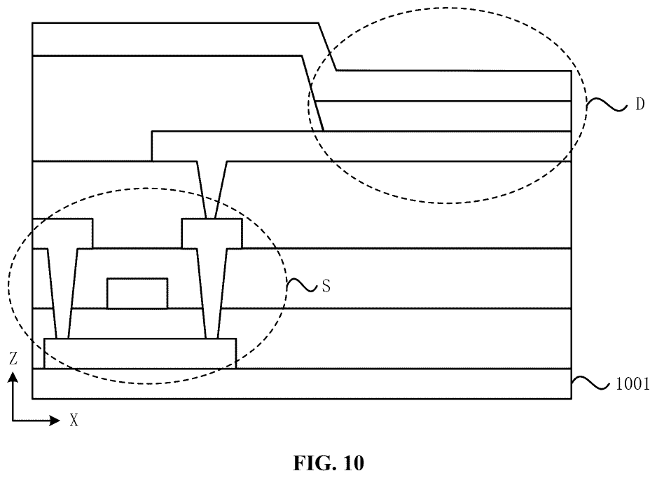

Optionally, FIG. 9 is a diagram illustrating the partial structure of another display panel according to the embodiments of the present invention. FIG. 10 is a diagram illustrating the structure of a film layer of a display panel according to the embodiments of the present invention. With reference to FIG. 9 and FIG. 10, each pixel P includes a light-emitting element D and a driver circuit S. Driver circuits S in pixels P are arranged in an array in a display region 101. The light-emitting element D is electrically connected to the driver circuit S. The display panel 100 also includes a base substrate 1001. The driver circuit S and the light-emitting element D are stacked on one side of the base substrate 1001. In the same first pixel P1, the distance between the light-emitting center o of the light-emitting element D and the geometric center o′ of the driver circuit S in a first direction X is a first distance L10. The value range of the difference N between first distances L10 of different first pixels P1 is 0 μm≤|N|≤10 μm. The first direction is parallel to a plane in which the base substrate 10 is located.

Specifically, the driver circuits S in the display region 101 are arranged in an array. In this manner, when the light-transmissive region 102 is located in the central region of the region surrounded by each driver circuit S around the light-transmissive region 102, the shortest distances between the geometric centers o′ of the driver circuits S around the light-transmissive region 102 and the light-transmissive region 102 can be kept uniform. Thus, the value range of the difference N between the first distances L10 of the first pixels P1 is set to 0 μm≤|N|≤10 μm so that the first distance L10 of each first pixel P1 varies within a small range. This can be considered that the first distance L10 of each first pixel P1 is consistent, and thus the distance between the light-emitting center o of the light-emitting element D of each first pixel P1 and the light-transmissive region 102 can be ensured to vary within a small range. Therefore, the phenomenon that the display black edge around light-transmissive region 102 is not uniform due to the difference between the first distances L10 of the first pixels P1 is not perceived by the human eye, thereby visually ensuring that the display black edge around the light-transmissive region 102 is consistent.

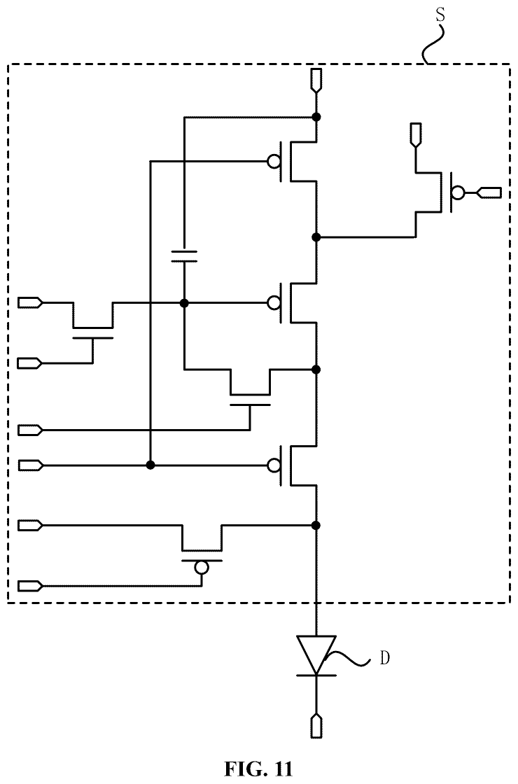

It is to be noted that in FIG. 10, the structure of a driver circuit S is only exemplarily represented by the structure of one transistor. In the embodiments of the present invention, a driver circuit may be composed of an active device and/or a passive device. The active device includes a transistor or the like. The passive device includes a capacitor, a resistor or the like. The embodiments of the present invention are not specifically limited thereto. In an example embodiment, as shown in FIG. 11, a driver circuit S may be a typical 7T1C (seven transistors and one storage capacitor) structure. The specific driving principle of the driver circuit S may refer to the description of the 7T1C circuit and the variant structure thereof in the related art, and details are not described herein.

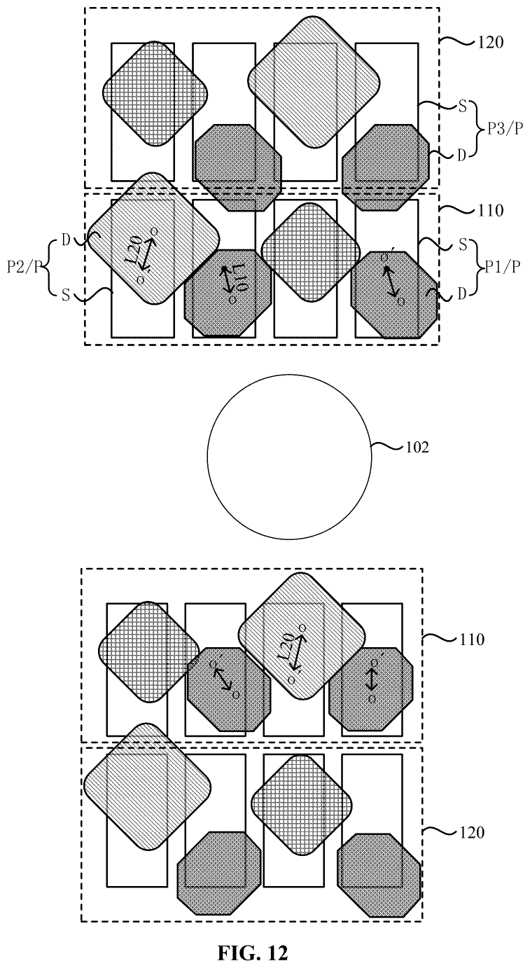

In an optional embodiment, as shown in FIG. 12, on the premise that the value range of the difference N between the first distances of the first pixels P1 is 0 μm≤|N|≤10 μm, the light-emitting center o of the light-emitting element D of each first pixel P1 is located on the side of the geometric center o′ of the driver circuit S facing the light-transmissive region 102. Thus, the distance between the light-emitting center o of each light-emitting element D and the light-transmissive region 102 can be kept uniform, the size of the non-light-emitting region around the light-transmissive region 102 can be ensured to be uniform, and the size of the non-light-emitting region around the light-transmissive region 102 can be minimized.

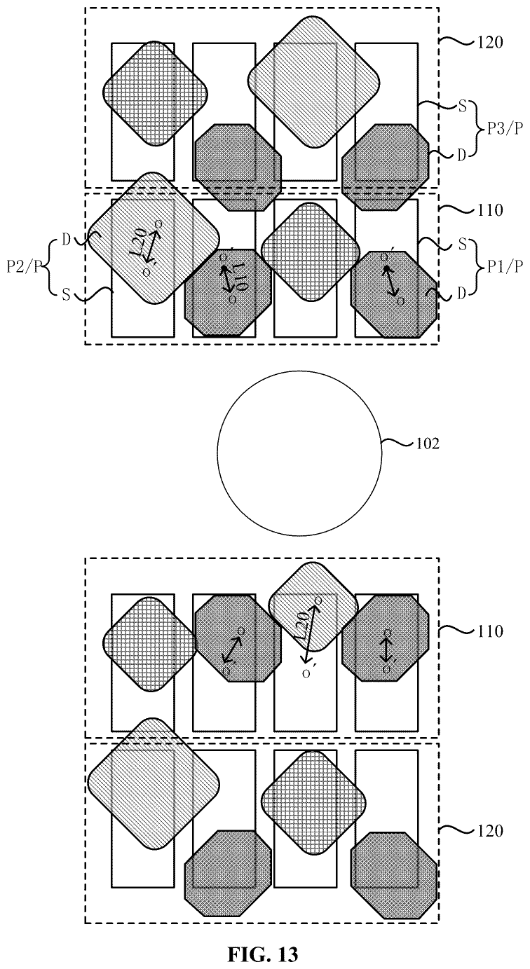

In another optional embodiment, as shown in FIG. 13, on the premise that the value range of the difference N between the first distances of the first pixels P1 is 0 μm≤|N|≤10 μm, the light-emitting center o of the light-emitting element D of each first pixel P1 is located on the side of the geometric center o′ of the driver circuit S facing away from the light-transmissive region 102. In this case, the distance between the light-emitting center o of each light-emitting element D and the light-transmissive region 102 can also be ensured to be uniform so that the size of the non-light-emitting region around the light-transmissive region 102 can be kept uniform.

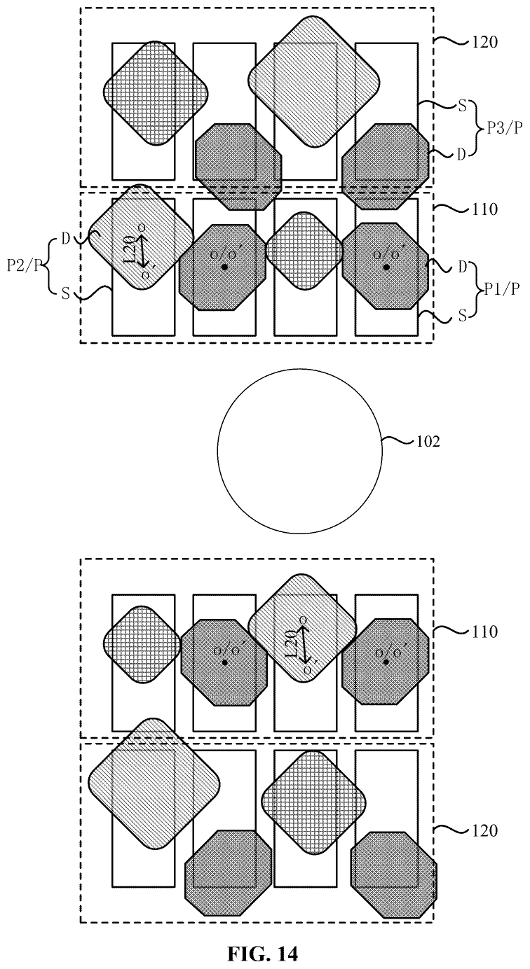

In another optional embodiment, as shown in FIG. 14, in the same first pixel P1, when the first distance L10 between the light-emitting center o of the light-emitting element D and the geometric center o′ of the driver circuit S is 0, the light-emitting center o of the light-emitting element D coincides with the geometric center o′ of the driver circuit S. Thus, the distance between the light-emitting center o of the light-emitting element D and the light-transmissive region 102 is the distance between the geometric center o′ of the driver circuit S and the light-transmissive region 102. When the distance between the geometric center o′ of the driver circuit S of each first pixel P1 and the light-transmissive region 102 is the same, the distance between the light-emitting center o of the light-emitting element D of each first pixel P1 and the light-transmissive region 102 is the same. Thus, the radiation range of the light emitted from the light-emitting element D of each first pixel P1 is kept uniform around the light-transmissive region 102. Further, the size of the non-light-emitting region around the light-transmissive region 102 can be kept uniform, thereby improving the display effect of the display panel.

It is to be noted that FIGS. 12 to 14 only exemplarily show the arrangement manners of the pixels on opposite sides of the light-transmissive region 102. Each pixel around the light-transmissive region 102 in the embodiments of the present invention may have the same or similar arrangement. The embodiments of the present invention are not specifically limited thereto.

Optionally, with reference to any one of FIGS. 12 to 14, part of pixels P in the first pixel group 110 are second pixels P2. In a second pixel P2, the distance between the light-emitting center o of the light-emitting element D and the geometric center o′ of the driver circuit S is a second distance L20. The second distance L20 is greater than the first distance L10. That is, the light-emitting center o of the light-emitting element D in a first pixel P1 is closer to the geometric center o′ of the driver circuit S in the first pixel P1, while the light-emitting center o of the light-emitting element D in a second pixel P2 is further from the geometric center o′ of the driver circuit S in the second pixel P2. In this manner, the first pixels P1 and second pixels P2 in the first pixel group 110 are differentially designed. Thus, when the distances between the light-emitting centers o of the light-emitting elements D of all pixels P in the first pixel group 110 and the geometric centers o′ of the driver circuits S of the all pixels P in the first pixel group 110 cannot be kept small, only the distances between the light-emitting centers o of the light-emitting elements D in the first pixels P1 in the first pixel group 110 D and the geometric center o′ of the driver circuits S in the first pixels P1 in the first pixel group 110 can be kept small, while the distances between the light-emitting centers o of the light-emitting elements D in the second pixels P2 and the geometric centers o′ of the driver circuits S in the second pixels P2 can be kept large. Compared with the related art, on the premise of ensuring that the size of the non-light-emitting region around the light-transmissive region 102 is kept uniform, only the setting positions of the light-emitting elements D and/or the driver circuits S in the first pixels P1 can be adjusted, while the setting positions of the light-emitting elements D and/or the driver circuits S in the second pixels P2 can be kept unchanged, thereby facilitating simplification of the layout design of the display panel, ensuring that most of pixels P in the display panel can maintain the original pixel arrangement manner, and making the display panel have a higher display light-emitting effect.

In addition, in other alternative embodiments, the first distance L10 may be greater than or equal to the second distance L20. The embodiments of the present invention are not specifically limited thereto on the premise that the size of the non-light-emitting region around the light-transmissive region 102 is kept uniform.

In an optional embodiment, the color of second pixels P2 may be the same as or different from the color of first pixels P1. When the color of the second pixels P2 is different from the color of the first pixels P1, the first pixels P1 and the second pixels P2 are differentially designed to ensure that the distance between the light-emitting center o of the light-emitting element D of each first pixel P1 of the same color in the first pixel group 110 and the geometric center o′ of the driver circuit S of the each first pixel P1 of the same color in the first pixel group 110 is consistent, and the distance between the light-emitting center o of the light-emitting element D of each second pixel P2 of the same color and the geometric center o′ of the driver circuit S of the each second pixel P2 of the same color is consistent. Thus, the radiation range of light emitted from each pixel P of the same color in the first pixel group 110 is consistent around the light-transmissive region 102. Further, the size of the non-light-emitting region around the light-transmissive region 102 is consistent, thereby improving the display effect of the display panel.

In an example embodiment, the light-emitting color of the first pixels P1 may be a color that is more sensitive to the human eye, for example, green. In this case, the first pixels P1 may be green pixels. The light-emitting color of the second pixels P2 may be a color that is less sensitive to the human eye, for example, blue. In this case, the second pixels P2 may be blue pixels. Alternatively, when the first pixels P1 include green pixels, the second pixels P2 may include blue pixels and red pixels. Alternatively, when the first pixels P1 include green pixels and red pixels, the second pixels P2 may include blue pixels. On the premise that the color of the second pixels P2 is different from the color of the first pixels P1, the embodiments of the present invention are not specifically limited the colors of the first pixels P1 and second pixels P2.

Optionally, with reference to any one of FIGS. 12 to 14, the display region also includes a second pixel group 120 located on the side of the first pixel group 110 facing away from the light-transmissive region 102. At least part of pixels P in the second pixel group 120 are third pixels P3. In the same third pixel P3, the distance between the light-emitting center o of the light-emitting element D and the geometric center o′ of the driver circuit S in a first direction is a third distance L30. In a third pixel P3 and a first pixel P1 of the same color, the third distance L30 is greater than the first distance L10.

Specifically, since the second pixel group 120 is located on the side of the first pixel group 110 facing away from the light-transmissive region 102, the light emitted from each pixel P in the second pixel group 120 has little or no effect on the size of the non-light-emitting region around the light-transmissive region 102. In this case, there may be a large distance between the light-emitting center o of the light-emitting element D in each pixel P in the second pixel group 120 and the geometric center o′ of the driver circuit S of the each pixel P in the second pixel group 120. Moreover, the distance between the light-emitting center o of the light-emitting element D in each pixel P in the second pixel group 120 and the geometric center o′ of the driver circuit S of the each pixel P in the second pixel group 120 may be the same or different. In this manner, in a first pixel P1 and a third pixel P3 of the same color, the first distance L10 is greater than the third distance L30, that is, the first pixel P1 and the third pixel P3 are differentially designed. Compared with the related art, on the premise of ensuring that the size of the non-light-emitting region around the light-transmissive region 102 is kept uniform, only the setting positions of the light-emitting elements D and/or the driver circuits S in first pixels P1 can be adjusted, while the setting positions of the light-emitting elements D and/or the driver circuits S in third pixels P3 can be kept unchanged, thereby facilitating simplification of the layout design of the display panel, ensuring that most of pixels P in the display panel can maintain the original pixel arrangement manner, and making the display panel have a higher display light-emitting effect.

In addition, in other alternative embodiments, the first distance L10 may be greater than or equal to the third distance L30. The embodiments of the present invention are not specifically limited thereto on the premise that the size of the non-light-emitting region around the light-transmissive region 102 is kept uniform.

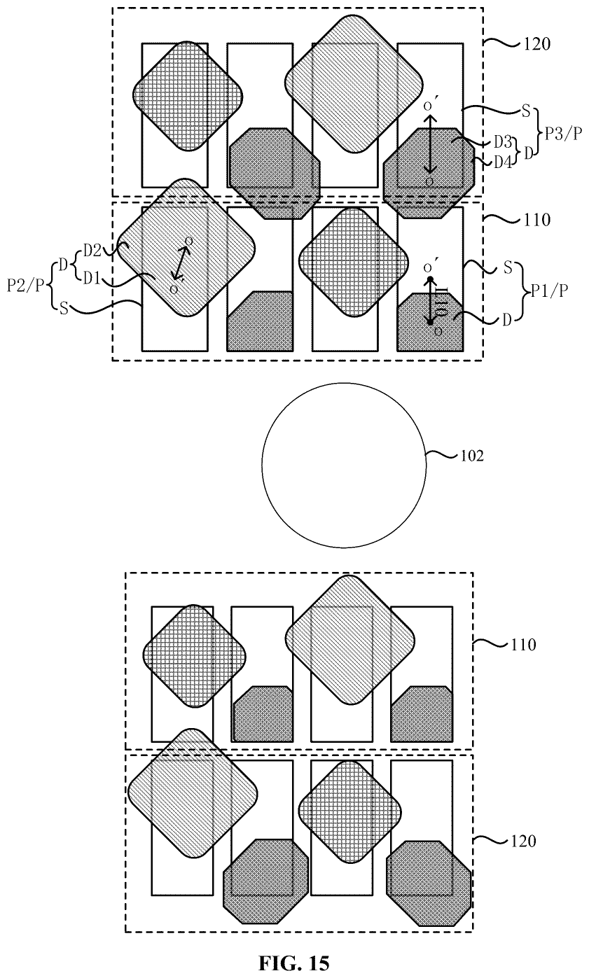

Optionally, FIG. 15 is a diagram illustrating the partial structure of another display panel according to the embodiments of the present invention. With reference to FIG. 10 and FIG. 15, in the case where the display panel 100 also includes the base substrate 1001, the each pixel P includes a light-emitting element D and a driver circuit S, the driver circuit S and the light-emitting element D are stacked on one side of the base substrate 1001, the driver circuits S in pixels P are arranged in an array in the display region, and the light-emitting element D is electrically connected to the driver circuit S, in the same first pixel P1, the orthographic projection of the light-emitting element D on the base substrate 1001 is located in the orthographic projection of the driver circuit S on the base substrate 1001.

Specifically, the driver circuits S in pixels P in the display region are arranged in an array. In this manner, when the light-transmissive region 102 is located in the central region of the region surrounded by each driver circuit S around the light-transmissive region 102, the shortest distance between each driver circuit S around the light-transmissive region 102 and the light-transmissive region 102 can be kept uniform. In this case, by setting that, in the first pixel P1, the orthographic projection of the light-emitting element D on the base substrate 1001 is located in the orthographic projection of the driver circuit S on the base substrate 1001, in the same first pixel P1, the distance between the light-emitting center o of the light-emitting element D and the geometric center o′ of the driver circuit S can be shortened. Thus, in the same first pixel P1, the distance between the light-emitting center o of the light-emitting element D and the light-transmissive region 102 can be kept uniform with the distance between the geometric center o′ of the driver circuit S and the light-transmissive region 102 so that the shortest distance between the light-emitting center o of the light-emitting element D of each first pixel P1 and the light-transmissive region 102 can be kept uniform. Further, the radiation range of the light emitted from the light-emitting element D can be kept uniform around the light-transmissive region 102, thereby ensuring that the size of the non-light-emitting region around the light-transmissive region 102 can be kept uniform and improving the display effect of the display panel.

It is to be noted that when, in the same first pixel P1, the orthographic projection of the light-emitting element D on the base substrate 1001 is located in the orthographic projection of the driver circuit S on the base substrate 1001, compared with the related art, the light-emitting element D in the first pixel P1 may have a smaller size. In this case, the size of the light-emitting element D of each first pixel P1 may be reduced in equal proportion, or the portion of the orthographic projection of the light-emitting element D that exceeds the orthographic projection of the driver circuit S may be removed. Alternatively, when, in the same first pixel P1, the orthographic projection of the light-emitting element D on the base substrate 1001 is located in the orthographic projection of the driver circuit S on the base substrate 1001, compared with the related art, the actual size of the light-emitting element D in the first pixel P1 may remain unchanged. In this case, a light-shielding layer may be disposed at the light emission side of the portion of the light-emitting element D that is orthogonally projected beyond the orthographic projection of the driver circuit S. Thus, only the portion of the light-emitting element D that is orthogonally projected in the orthographic projection of the driver circuit S can emit light. In this manner, by reducing the size of the portion of the light-emitting element D in a first pixel P1 facing the light-transmissive region that can normally emit light, only the setting positions and the size of the light-emitting elements D of first pixels P1 around the light-transmissive region 102 can be adjusted, without the need to adjust the setting positions and the size of the light-emitting elements D in pixels P at other positions. This simplifies the design of the display panel on the premise of ensuring that the size of the non-light-emitting region around the light-transmissive region 102 is kept uniform.

It is to be understood that, on the premise of ensuring that the shortest distance between the light-emitting center o of the light-emitting element D of each first pixel P1 and the light-transmissive region 102 can be kept uniform, the specific arrangement manner of the light-emitting element D in the embodiments of the present invention includes but is not limited to the preceding various arrangement manners.

Optionally, with continued reference to FIG. 10 and FIG. 15, at least part of pixels P in the first pixel group 110 are second pixels P2. The light-emitting element D of each second pixel P2 includes a first light-emitting portion D1 and a second light-emitting portion D2. In a direction Z perpendicular to a plane in which the base substrate 1001 is located and in the same second pixel P2, the first light-emitting portion D1 overlaps the driver circuit S, and the second light-emitting portion D2 does not overlap the driver circuit S.

The first light-emitting portion D1 and second light-emitting portion D2 of the light-emitting element D in a second pixel P2 may be an integrated structure. In the case where the light-emitting element D in a second pixel P2 includes a first light-emitting portion D1 and a second light-emitting portion D2, the distance between the light-emitting center o of the light-emitting element D in the second pixel P2 and the geometric center o′ of the driver circuit S in the second pixel P2 may be the same as or different from the distance between the light-emitting center o of the light-emitting element D in a first pixel P1 and the geometric center o′ of the driver circuit S in the first pixel P1. The embodiments of the present invention are not specifically limited thereto.

Specifically, the light-emitting element D in each pixel P in the display panel is arranged in accordance with a certain rule to satisfy display light-emitting requirements such as pixel borrowing. Therefore, when the driver circuits S in pixels P are arranged in an array, the light-emitting elements D in part of the pixels P may be arranged deviating from the driver circuits S in the part of the pixels P. In this case, the light-emitting elements D include portions that overlap the driver circuits S and portions that do not overlap the driver circuits S. Each part of the light-emitting element D in a first pixel P1 is overlapped the driver circuit S in the first pixel P1. In a second pixel P2, the light-emitting element D includes a first light-emitting portion D1 that overlaps the driver circuit S and a second light-emitting portion D2 that does not overlap the driver circuit S. That is, the first pixels P1 and the second pixels P2 in the first pixel group 110 are differentially designed. Thus, on the premise of ensuring that the shortest distances between the light-emitting centers o of the light-emitting elements D in the first pixels P1 in the first pixel group 110 located around the light-transmissive region 102 and the light-transmissive region 102 are kept uniform, the setting positions of the light-emitting elements D in the second pixels P2 in the first pixel group 110 satisfy conditions such as pixel arrangement and pixel borrowing, thereby making the display panel have a higher display light-emitting effect.

In addition, first pixels P1 and second pixels P2 are differentially designed. Compared with the related art, on the premise of ensuring that the size of the non-light-emitting region around the light-transmissive region 102 is kept uniform, only the setting positions of the light-emitting elements D and/or the driver circuits S in first pixels P1 can be adjusted, while the setting positions of the light-emitting elements D and/or the driver circuits S in the second pixels P2 can be kept unchanged, thereby facilitating simplification of the layout design of the display panel, ensuring that most of pixels P in the display panel can maintain the original pixel arrangement manner, and making the display panel have a higher display light-emitting effect.

Optionally, with continued reference to FIG. 10 and FIG. 15, in the case where the display region also includes the second pixel group 120 located on the side of the first pixel group 110 facing away from the light-transmissive region 102, and at least part of the pixels P in the second pixel group 120 are the third pixels P3, the light-emitting element D in each third pixel P3 may include a third light-emitting portion D3 and a fourth light-emitting portion D4. In the direction Z perpendicular to a plane in which the base substrate 1001 is located and in the same third pixel P3, the third light-emitting portion D3 overlaps the driver circuit S, and the fourth light-emitting portion D4 does not overlap the driver circuit S.

The third light-emitting portion D3 and fourth light-emitting portion D4 of the light-emitting element D in a third pixel P3 may also be an integrated structure. In this case, the distance between the light-emitting center o of the light-emitting element D in the third pixel P3 and the geometric center o′ of the driver circuit S in the third pixel P3 may be the same as or different from the distance between the light-emitting center o of the light-emitting element D in a first pixel P1 and the geometric center o′ of the driver circuit S in the first pixel P1. The embodiments of the present invention are not specifically limited thereto.

Specifically, since the second pixel group 120 is located on the side of the first pixel group 110 facing away from the light-transmissive region 102, the light emitted from each pixel P in the second pixel group 120 has little or no effect on the size of the non-light-emitting region around the light-transmissive region 102. In this case, each part of the light-emitting element D in a first pixel P1 is overlapped the driver circuit S in the first pixel P1. In a third pixel P3, the light-emitting element D includes a third light-emitting portion D3 that overlaps the driver circuit S and a fourth light-emitting portion D4 that does not overlap the driver circuit S. That is, first pixels P1 in the first pixel group 110 facing the light-transmissive region 102 and third pixels P3 in the second pixel group 120 facing away from the light-transmissive region 102 are differentially designed. Thus, on the premise of ensuring that the shortest distances between the light-emitting centers o of the light-emitting elements D in the first pixels P1 in the first pixel group 110 located around the light-transmissive region 102 and the light-transmissive region 102 are kept uniform, the setting positions of the light-emitting elements D in the third pixels P3 in the second pixel group 120 can satisfy corresponding pixel arrangement and pixel borrowing conditions, facilitating the display panel to have a higher display light-emitting effect.

In addition, first pixels P1 and third pixels P3 are differentially designed. Compared with the related art, on the premise of ensuring that the size of the non-light-emitting region around the light-transmissive region 102 is kept uniform, only the setting positions of the light-emitting elements D and/or the driver circuits S in first pixels P1 can be adjusted, while the setting positions of the light-emitting elements D and/or the driver circuits S in the third pixels P3 can be kept unchanged, thereby facilitating simplification of the layout design of the display panel, ensuring that most of pixels P in the display panel can maintain the original pixel arrangement manner, and making the display panel have a higher display light-emitting effect.

It is to be understood that the colors of the first pixels P1 and second pixels P2 may be the same or different in the embodiments. Similarly, the colors of the first pixels P1 and third pixels P3 may be the same or different. This may be designed according to actual requirements, and the embodiments of the present invention are not specifically limited thereto.

In an optional embodiment, as shown in FIG. 15, in a third pixel P3 and a first pixel P1 of the same color, the area of the light-emitting element D in the third pixel P3 is larger than the area of the light-emitting element D in the first pixel P1. In this case, of the light-emitting element D in the third pixel P3, the area of the third light-emitting portion D3 whose orthographic projection overlaps the driver circuit S in the third pixel P3 may be kept uniform with the area of the light-emitting element D in the first pixel P1. Of the light-emitting element D in the third pixel P3, the area of the fourth light-emitting portion D4 whose orthographic projection does not overlap the driver circuit S in the third pixel P3 is the area difference between the light-emitting element D in the third pixel P3 and the light-emitting element D in the first pixel P1.

In this manner, by reducing the area of the light-emitting element in the first pixel P1, the purpose that the orthographic projection of the light-emitting element D in the first pixel P1 is all located in the orthographic projection of the driver circuit S in the first pixel P1 is achieved. The light-emitting element D in the third pixel P3 facing away from the light-transmissive region 102 can have a larger area so that the light emitted from the light-emitting element D in the third pixel P3 facing away from the light-transmissive region 102 can be ensured to have a larger radiation range to ensure that the display panel has higher display brightness.

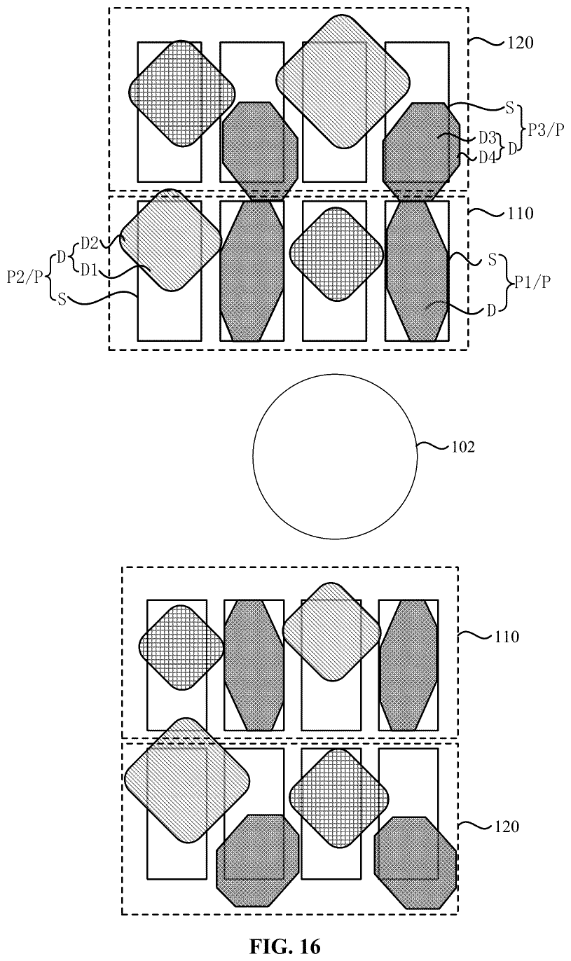

In another alternative embodiment, as shown in FIG. 16, in the case where the display region also includes the second pixel group 120 located on the side of the first pixel group 110 facing away from the light-transmissive region 102, and at least part of the pixels P in the second pixel group 120 are the third pixels P3, for a third pixel P3 and a first pixel P1 of the same color, the area of the light-emitting element D in the third pixel P3 may also be the same as the area of the light-emitting element D in the first pixel P1. In this case, for the first pixel P1 and the third pixel P3 of the same color, the light emitted from the light-emitting elements D in the first pixel P1 and the third pixel P3 can be ensured to have the same radiation range. Thus, the display brightness of the display region that is closer to the light-transmissive region 102 can be kept uniform with the display brightness of the display region that is farther from the light-transmissive region 102, thereby facilitating the improvement of the display uniformity of the display panel.

It is to be understood that when the area of the light-emitting element D in the first pixel P1 and the area of the light-emitting element D in the third pixel P3 are kept uniform, the light-emitting element D in the third pixel P3 may still include the third light-emitting portion D3 that overlaps the driver circuit S in the third pixel P3 and the fourth light-emitting portion D4 that does not overlap the driver circuit S in the third pixel P3, while the light-emitting element D in the first pixel P1 includes merely the light-emitting portion that overlaps the driver circuit S in the first pixel P1. In this case, the area of the light-emitting element D in the first pixel P1 may be set to be equivalent to the area of the driver circuit S in the first pixel P1, and the area of the light-emitting element D in the third pixel P3 may be set to be equivalent to the area of the driver circuit S in the third pixel P3. Thus, the light-emitting element D in the first pixel P1 and the light-emitting element D in the third pixel P3 can be ensured to have a large area so that the display panel has higher display brightness. The light-emitting element D in the first pixel P1 and the light-emitting element D in the third pixel P3 may be designed according to actual requirements, and the embodiments of the present invention include, but are not limited to, the preceding setting manner.

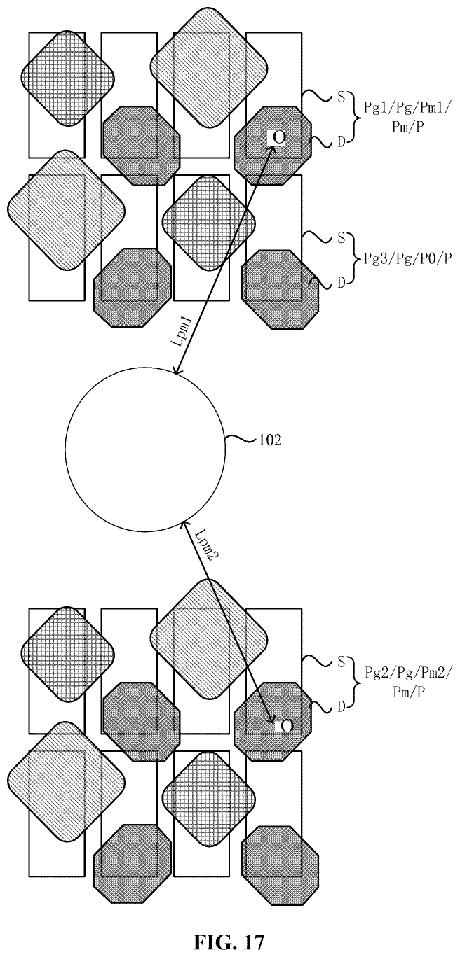

Optionally, FIG. 17 is a diagram illustrating the partial structure of another display panel according to the embodiments of the present invention. As shown in FIG. 17, a non-light-emitting region includes a black pixel P0. The brightness of the black pixel P0 is 0 nit.

The brightness of the black pixel P0 is 0 nit, that is, when the display panel displays an image, the black pixel P0 does not emit light for display. In this case, part of pixels P around a light-transmissive region 102 and closer to the light-transmissive region 102 may be used as black pixels P0. Thus, the radiation range of the light emitted from each pixel P emitting light for display around the light-transmissive region 102 is kept uniform around the light-transmissive region 102 so that the size of the non-light-emitting region around the light-transmissive region 102 is kept uniform. That is, when the display panel performs image display, the surrounding of the light-transmissive region 102 can have a uniform display black edge.

Exemplarily, as shown in FIG. 17, in pixels Pg located on opposite sides of the light-transmissive region 102 and of the same color, the distance between a pixel Pg3 and the light-transmissive region 102 is relatively close, while the distance between a pixel Pg1 and the light-transmissive region 102 and the distance between a pixel Pg2 and the light-transmissive region 102 are relatively far. Moreover, the pixels Pg1 and Pg2, which are located on opposite sides of the light-transmissive region 102 and have the same color, have similar distances from the light-transmissive region 102. In this case, the pixel Pg3 located on one side of the light-transmissive region 102 can be used as a black pixel P0, while the pixels Pg1 and Pg2 are pixels normally emitting light for display. Therefore, when the display panel displays an image, the black pixel P0 does not emit light for display, while the pixels Pg1 and Pg2 normally emit light for display. Moreover, the radiation range of the light emitted from the pixels Pg1 and Pg2 can be kept uniform around the light-transmissive region 102 so that the size of the non-light-emitting regions on opposite sides of the light-transmissive region 102 can be kept uniform, and a uniform display black edge can be disposed around the light-transmissive region 102, thereby improving the display effect of the display panel.

It is to be understood that FIG. 17 only exemplarily shows the arrangement manner of black pixels P0 on opposite sides of the light-transmissive region 102. In the embodiments of the present invention, black pixels P0 among pixels disposed on other sides around the light-transmissive region 102 are arranged in a similar manner. For the same part, reference may be to the preceding description, and details are not described herein. Similarly, exemplary description has been given above only through the setting manner of black pixels P0 in pixels Pg of one color. In the embodiments of the present invention, the color of black pixels P0 may be various, and the embodiments of the present invention are not specifically limited thereto.

Optionally, in the radial direction of the light-transmissive region 3, the arrangement number of black pixels 12 is less than or equal to 5. In this manner, on the premise that the size of the display black edge around the light-transmissive region 102 is kept uniform, the size of the non-light-emitting region around the light-transmissive region 102 can be ensured to be as small as possible, thereby improving the screen-to-body ratio of the display panel and facilitating the improvement of the display effect of the display panel.

It is to be understood that when the display panel displays a corresponding image, the manner of controlling the brightness of a black pixel P0 to be 0 nit may include, but is not limited to, not providing the corresponding drive signal for the light-emitting element D of the black pixel P0 or providing the drive signal corresponding to 0 grayscale for the light-emitting element D of the black pixel P0. On the premise of ensuring that the display brightness of a black pixel P0 is 0 nit, the embodiments of the present invention do not specifically limit the manner in which the brightness of the black pixel P0 is controlled to be 0 nit.

Optionally, with continued reference to FIG. 17, a display region includes multiple light-emitting pixels Pm adjacent to the light-transmissive region 102 and at least partially surrounding the light-transmissive region 102. Black pixels P0 are located between the light-emitting pixels Pm and the light-transmissive region 102. Light-emitting pixels Pm of the same color include a first light-emitting pixel Pm1 and a second light-emitting pixel Pm2. The distance between the light-emitting center o of the first light-emitting pixel Pm1 and the light-transmissive region 102 is a first distance Lpm1. The distance between the light-emitting center o of the second light-emitting pixel Pm2 and the light-transmissive region 102 is a second distance Lpm2. The first distance Lpm1 is greater than the second distance Lpm2. The number of black pixels P0 located between the first light-emitting pixel Lpm1 and the light-transmissive region 102 is greater than the number of black pixels P0 located between the second light-emitting pixel Pm2 and the light-transmissive region 102.

The light-emitting pixel Pm adjacent to the light-transmissive region 102 may be the pixel P whose distance from the light-transmissive region 102 is the shortest among pixels P located on the same side of the light-transmissive region 102 that can normally emit light for display. The distance between a black pixel P0 and the light-transmissive region 102 is generally smaller than the distance between a light-emitting pixel Pm and the light-transmissive region 102.

Specifically, the black pixel P0 is a pixel P whose distance from the light-transmissive region 102 is relatively close, and the light-emitting pixel Pm on the side of the black pixel P0 facing away from the light-transmissive region 102 is a pixel P whose distance from the light-transmissive region 102 is relatively far. To ensure that light-emitting pixels Pm around the light-transmissive region 102 satisfy the corresponding pixel arrangement, and the distance between the light-emitting center of each light-emitting pixel Pm and the light-transmissive region 102 is kept as uniform as possible, the number of black pixels P0 between first light-emitting pixels Pm1 whose distance from the light-transmissive region 102 is relatively far and the light-transmissive region 102 may be larger, and the number of black pixels between second light-emitting pixels Pm2 whose distance from the light-transmissive region 102 is relatively close and the light-transmissive region 102 may be smaller. Thus, on the premise that the size of the non-light-emitting region around the light-transmissive region 102 is kept uniform, the display effect of the display panel can be improved.

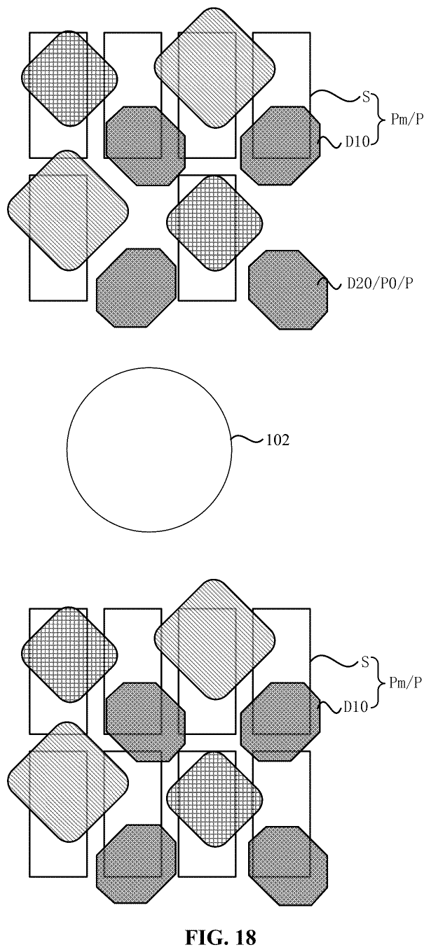

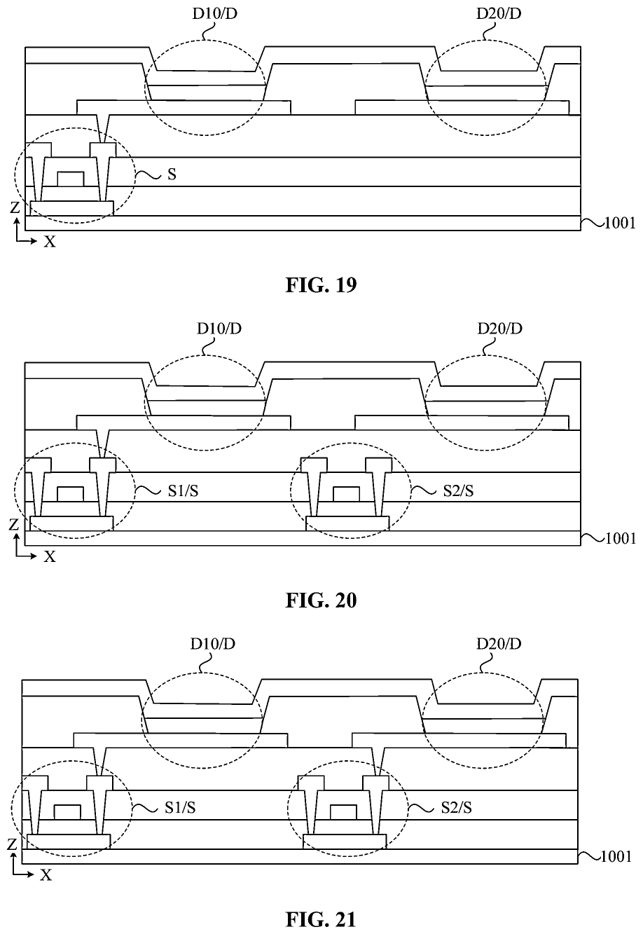

Optionally, FIG. 18 is a diagram illustrating the partial structure of another display panel according to the embodiments of the present invention. FIG. 19 is a diagram illustrating the structure of a film layer of another display panel according to the embodiments of the present invention. With reference to FIG. 18 and FIG. 19, when the display panel also includes the base substrate 1001 and the driver circuit S and the light-emitting element D located on one side of the base substrate 1001, the light-emitting element D may include a first light-emitting element D10 and a second light-emitting element D20. The light-emitting pixel Pm includes the first light-emitting element D10 and the driver circuit S electrically connected to the first light-emitting element D10. The black pixel P0 includes the second light-emitting element D20. The second light-emitting element D20 and the driver circuit S are not connected to each other.

Specifically, since the light-emitting pixel Pm includes the first light-emitting element D10 and the driver circuit S which are electrically connected to each other, the driver circuit S can provide a drive signal for the first light-emitting element D10 to drive the first light-emitting element D10 to emit light for display. The driver circuit S can receive a corresponding data signal and generate a corresponding drive signal according to the data signal. The data signal received by the driver circuit S may be an analog signal or a digital signal, and the embodiments of the present invention are not specifically limited thereto. Similarly, the drive signal generated by the driver circuit S may be a voltage signal or a current signal, and the embodiments of the present invention are also not specifically limited thereto. For example, the data signal received by the driver circuit S is an analog signal, and the drive signal generated by the driver circuit S is a current signal. The larger the current value of the drive signal received by the first light-emitting element D10, the higher the brightness of the first light-emitting element D10 for emitting light for display. A data signal corresponding to the display brightness level (that is, grayscale) of the first light-emitting element D10 is provided for the driver circuit S so that the driver circuit S generates a drive signal according to the data signal. Thus, the display brightness of the first light-emitting element D10 can be controlled. The black pixel P0 may include merely the second light-emitting element D20, so no corresponding driver circuit S in the black pixel P0 drives the second light-emitting element D20 to emit light for display. Thus, when the display panel displays a corresponding image, the second light-emitting element D20 does not emit light for display, that is, the display brightness of the second light-emitting element D20 is 0 nit. In this manner, by not providing the driver circuit S electrically connected to the second light-emitting element D20 in the black pixel P0 in the display panel, the second light-emitting element D20 can be kept at the display brightness of 0 nit continuously. On the premise of ensuring that the size of the non-light-emitting region around the light-transmissive region 102 is kept uniform, the number of driver circuits disposed in the display panel can be reduced to simplify the structure of the display panel. Alternatively, the number of driver circuits S corresponding to first light-emitting elements D10 can be increased, that is, the number of light-emitting pixels Pm is increased, to increase the resolution of the display panel.

It is to be noted that FIG. 18 and FIG. 19 only exemplarily show that the driver circuit S corresponding to the second light-emitting element D20 in the black pixel P0 is not disposed. However, the driver circuit S corresponding to the second light-emitting element D20 may be disposed in the embodiments of the present invention. As shown in FIG. 20, the display panel includes the driver circuit S1 and the driver circuit S2 corresponding to the first light-emitting element D10 and the second light-emitting element D20 in a one-to-one manner. The driver circuit S1 corresponding to the first light-emitting element D10 is electrically connected to the first light-emitting element D10 by a via. The driver circuit S2 corresponding to the second light-emitting element D20 and the second light-emitting element D20 are not connected to each other. In this case, the second light-emitting element D20 likewise does not receive a corresponding drive signal, so the second light-emitting element D20 does not emit light for display.

In other optional embodiments of the embodiments of the present invention, as shown in FIG. 21, when the display panel includes the base substrate 1001 and the driver circuit S and the light-emitting element D located on one side of the base substrate 1001, the light-emitting element D includes the first light-emitting element D10 and the second light-emitting element D20, and the driver circuit S includes the first driver circuit S1 and the second driver circuit S2, the light-emitting pixel Pm includes the first light-emitting element D10 and the first driver circuit S1 electrically connected to the first light-emitting element D10, and the black pixel P0 includes the second light-emitting element D20 and the second driver circuit S2 electrically connected to the second light-emitting element D20. In this manner, the first driver circuit S1 and the second driver circuit S2 may still be arranged in an array. The via connected to the first light-emitting element D10 and the first driver circuit S1 and the via connected to the second light-emitting element D20 and the second driver circuit S2 may be set at the same time, thereby simplifying the design manner of the display panel.

It is to be understood that since the first driver circuit S1 electrically connected to the first light-emitting element D10 and the second driver circuit S2 electrically connected to the second light-emitting element D20 are disposed in the display panel, when the display panel performs image display, a data signal corresponding to the display grayscale of the first light-emitting element D10 driven by each first driver circuit S1 may be provided for the each first driver circuit S1, and a data signal corresponding to 0 grayscale is provided for each second driver circuit S2. Thus, the brightness level at which the second light-emitting element D20 is driven to emit light for display by the drive signal generated by the second driver circuit S2 is 0 grayscale, that is, the brightness of the second light-emitting element D20 is 0 nit.

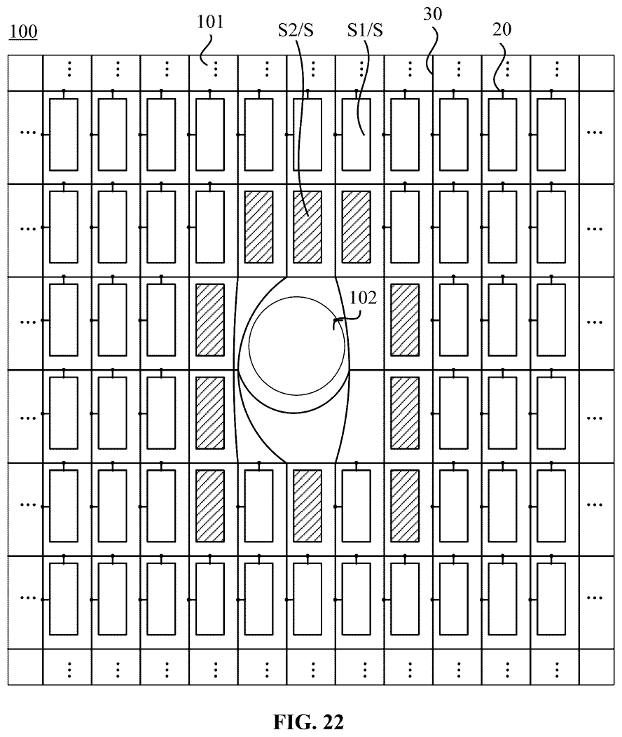

In other optional embodiments, FIG. 22 is a diagram illustrating the structure of driving circuits arranged in an array in a display panel according to embodiments of the present invention. With reference to FIG. 21 and FIG. 22, the second driver circuit S2 is disposed in a manner of levitation, that is, the second driver circuit S2 may not receive any signal.

Exemplarily, when multiple scan signal lines 20 and multiple data signal lines 30 are disposed in the display region 101 in the display panel 100, first driver circuits S1 located in the same row are electrically connected to the same scan signal line 20, and first driver circuits S1 located in the same column are electrically connected to the same data signal line 30. Thus, the scan signal transmitted by the scan signal line 20 electrically connected to a first driver circuit S1 can control the write time of the data signal transmitted by the data signal line 30 electrically connected to the first driver circuit S1, thereby ensuring that first driver circuits S1 in light-emitting pixels Pm can receive corresponding data signals in a one-to-one manner, further controlling the display panel 100 to present a rich and colorful image. Second driver circuits S2 are not electrically connected to the scan signal lines 20 and the data signal lines 30. Therefore, the second driver circuits S2 do not receive scan signals and data signals. Thus, the second driver circuits S2 do not generate the corresponding power consumption, facilitating the low power consumption of the display panel 100.

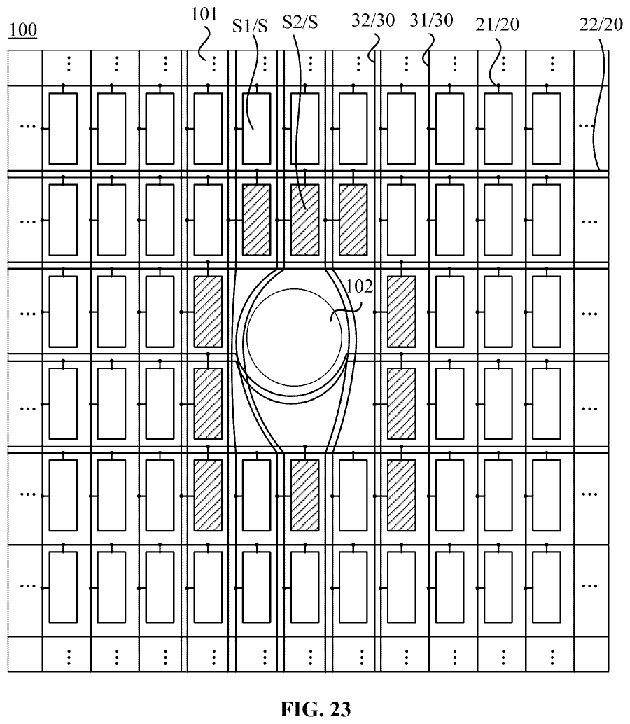

In another optional embodiment, FIG. 23 is a diagram illustrating the structure of driving circuits arranged in an array in another display panel according to embodiments of the present invention. With reference to FIG. 21 and FIG. 23, the first driver circuit S1 and the second driver circuit S2 are disposed independently, that is, the first driver circuit S1 and the second driver circuit S2 are not connected to each other.

Exemplarily, when multiple scan signal lines 20 and multiple data signal lines 30 are disposed in the display region 101 in the display panel 100, the scan signal lines 20 may include a first scan signal line 21 and a second scan signal line 22, and the data signal lines 30 may include a first data signal line 31 and a second data signal line 32. First driver circuits S1 located in the same row are electrically connected to the same first scan signal line 21. First driver circuits S1 located in the same column are electrically connected to the same first data signal line 31. Thus, the scan signal transmitted by the first scan signal line 21 electrically connected to a first driver circuit S1 can control the write time of the data signal transmitted by the first data signal line 31 electrically connected to the first driver circuit S1. Second driver circuits S2 located in the same row are electrically connected to the same second scan signal line 22. Second driver circuits S2 located in the same column are electrically connected to the same second data signal line 32. Thus, the second driver circuits S2 can separately receive scan signals transmitted by second scan signal lines 22 and data signals transmitted by second data signal lines 32. In this manner, first driver circuits S1 are not electrically to second driver circuits S2 by the data signal lines 30 and/or the scan signal lines 20. Thus, the first driver circuits S1 and the second driver circuits S2 are independent from each other. Therefore, when the display panel displays the corresponding image, the second data signal lines may not transmit any data signal, or the second data signal lines may transmit merely data signals corresponding to 0 grayscale to ensure that the display brightness of the second light-emitting element D20 is 0 nit, thereby ensuring that the size of the non-light-emitting region around the light-transmissive region 102 is kept uniform.

It is to be understood that the preceding only exemplarily describes the case where the second driver circuit S2 is disposed in a manner of levitation or the first driver circuit S1 and the second driver circuit S2 are independent from each other. In the embodiments of the present invention, on the premise of ensuring that the first driver circuit S1 normally drives the first light-emitting element D10 to normally emit light for display, and the second driver circuit S2 controls the second light-emitting element D20 not to emit light, the arrangement manner of the first driver circuit S1 and second driver circuit S2 can be determined as required, and the embodiments of the present invention are not specifically limited thereto.

Based on the same inventive concept, the embodiments of the present invention also provide a display device. The display device includes the display panel 100 provided in the embodiments of the present invention. Therefore, the display device has the technical features of the display panel provided in the embodiments of the present invention and can achieve the beneficial effects of the display panel provided in the embodiments of the present invention. Similarities may be referred to the preceding description of the display panel provided in the embodiments of the present invention and are not repeated herein.

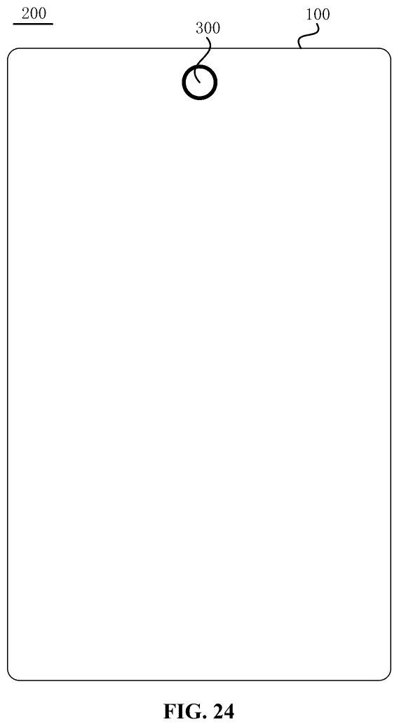

Exemplarily, FIG. 24 is a diagram illustrating the structure of a display device according to embodiments of the present invention. As shown in FIG. 24, the display device includes the display panel 100 provided in the embodiments of the present invention. The display device 200 provided in the embodiments of the present invention may be any display device provided with a photosensitive sensor 300. The photosensitive sensor 300 is disposed in the light-transmissive region of the display panel 100. The photosensitive sensor 300 may include, but is not limited to, an image acquisition sensor or an infrared sensor. Accordingly, the display device 200 includes, but is not limited to, the following categories: mobile phone, laptop, desktop display, tablet computer, and wearable display device. The embodiments of the present invention are not particularly limited thereto.

It is to be understood that various forms of working processes of driver circuits shown above may be adopted with stages reordered, added, or deleted. For example, each stage of the working process of each driver circuit described in the present invention may be performed in parallel, sequentially or in different orders, as long as the desired results of the technical solutions of the present invention can be implemented, and no limitation is imposed herein.

The preceding specific embodiments do not constitute a limitation on the protection scope of the present invention. It is to be understood by those skilled in the art that various modifications, combinations, sub-combinations, and substitutions may be performed according to design requirements and other factors. Any modifications, equivalent replacements, improvements, and the like within the spirit and principle of the present invention shall fall within the protection scope of the present invention.

What is claimed is:

1. A display panel, comprising a light-transmissive region, a display region at least partially surrounding the light-transmissive region, and a non-light-emitting region located between the light-transmissive region and the display region, wherein
in a radial direction of the light-transmissive region, a difference in a size of the non-light-emitting region located around the light-transmissive region is ΔD, wherein 0 μm≤|ΔD|≤10 μm.

2. The display panel of claim 1, wherein the display region comprises a plurality of pixel units, and a pixel unit of the plurality of pixel units comprises a plurality of pixels of different colors;
at least part of a plurality of pixels surrounding the light-transmissive region form a first pixel group;
at least part of pixels in the first pixel group are first pixels; and
a difference between shortest distances from light-emitting centers of the first pixels located around the light-transmissive region and of a same color to the light-transmissive region is M, wherein, 0 μm≤|M|≤10 μm.

3. The display panel of claim 2, wherein a pixel of the plurality of pixels comprises a light-emitting element and a driver circuit, driver circuits of the plurality of pixels are arranged in an array in the display region, and the light-emitting element is electrically connected to the driver circuit;
the display panel further comprises a base substrate, and the driver circuit and the light-emitting element are stacked on one side of the base substrate; and
in a same first pixel of the first pixels, a distance between a light-emitting center of the light-emitting element and a geometric center of the driver circuit in a first direction is a first distance, and a value range of a difference N between first distances of different first pixels of the first pixels is 0 μm≤|N|≤10 μm, wherein the first direction is parallel to a plane in which the base substrate is located.

4. The display panel of claim 3, wherein a light-emitting center of the light-emitting element in each of the first pixels is located on a side of a geometric center of the driver circuit facing the light-transmissive region; or
a light-emitting center of the light-emitting element in each of the first pixels is located on a side of a geometric center of the driver circuit facing away from the light-transmissive region.

5. The display panel of claim 3, wherein in a same first pixel, the light-emitting center of the light-emitting element coincides with the geometric center of the driver circuit.

6. The display panel of claim 3, wherein part of pixels in the first pixel group are second pixels; in a second pixel of the second pixels, a distance between a light-emitting center of the light-emitting element and a geometric center of the driver circuit is a second distance; and the second distance is greater than the first distance.

7. The display panel of claim 6, wherein color of the second pixels is different from color of the first pixels.

8. The display panel of claim 3, wherein the display region further comprises a second pixel group located on a side of the first pixel group facing away from the light-transmissive region, and at least part of pixels in the second pixel group are third pixels;
in a same third pixel of the third pixels, a distance between a light-emitting center of the light-emitting element and a geometric center of the driver circuit in the first direction is a third distance; and
in a third pixel and a first pixel of a same color, the third distance is greater than the first distance.

9. The display panel of claim 2, wherein a pixel of the plurality of pixels comprises a light-emitting element and a driver circuit, driver circuits of the plurality of pixels are arranged in an array in the display region, and the light-emitting element is electrically connected to the driver circuit;
the display panel further comprises a base substrate, and the driver circuit and the light-emitting element are stacked on one side of the base substrate; and
in a same first pixel of the first pixels, an orthographic projection of the light-emitting element on the base substrate is located in an orthographic projection of the driver circuit on the base substrate.

10. The display panel of claim 9, wherein at least part of pixels in the first pixel group are second pixels; a light-emitting element in a second pixel of the second pixels comprises a first light-emitting portion and a second light-emitting portion; and, in a direction perpendicular to a plane in which the base substrate is located and in a same second pixel of the second pixels, the first light-emitting portion overlaps the driver circuit, and the second light-emitting portion does not overlap the driver circuit.

11. The display panel of claim 9, wherein the display region further comprises a second pixel group located on a side of the first pixel group facing away from the light-transmissive region; and
at least part of pixels in the second pixel group are third pixels; a light-emitting element in a third pixel of the third pixels comprises a third light-emitting portion and a fourth light-emitting portion; and, in a direction perpendicular to a plane in which the base substrate is located and in a same third pixel of the third pixels, the third light-emitting portion overlaps the driver circuit, and the fourth light-emitting portion does not overlap the driver circuit.

12. The display panel of claim 11, wherein in a third pixel and a first pixel of a same color, area of a light-emitting element in the third pixel is larger than area of a light-emitting element in the first pixel.

13. The display panel of claim 11, wherein the display region further comprises a second pixel group located on a side of the first pixel group facing away from the light-transmissive region; and
at least part of pixels in the second pixel group are third pixels; in a third pixel and a first pixel of a same color, area of a light-emitting element in the third pixel is the same as area of a light-emitting element in the first pixel.

14. The display panel of claim 1, wherein the non-light-emitting region comprises black pixels, and brightness of the black pixels is 0 nit.

15. The display panel of claim 14, wherein the display region comprises a plurality of light-emitting pixels adjacent to the light-transmissive region and at least partially surrounding the light-transmissive region;
the black pixels are located between the plurality of light-emitting pixels and the light-transmissive region; and
light-emitting pixels of a same color comprise a first light-emitting pixel and a second light-emitting pixel; a distance between a light-emitting center of the first light-emitting pixel and the light-transmissive region is a first distance, and a distance between a light-emitting center of the second light-emitting pixel and the light-transmissive region is a second distance,
wherein the first distance is greater than the second distance, and a number of black pixels located between the first light-emitting pixel and the light-transmissive region is greater than a number of black pixels located between the second light-emitting pixel and the light-transmissive region.

16. The display panel of claim 14, wherein in the radial direction of the light-transmissive region, an arrangement number of the black pixels is less than or equal to 5.

17. The display panel according to claim 15, further comprising a base substrate and a driver circuit and a light-emitting element located on one side of the base substrate, wherein the light-emitting element comprises a first light-emitting element and a second light-emitting element; and
a light-emitting pixel of the plurality of light-emitting pixels comprises the first light-emitting element and the driver circuit electrically connected to the first light-emitting element, a black pixel of the black pixels comprises the second light-emitting element, and the second light-emitting element and the driver circuit are not connected to each other.

18. The display panel according to claim 15, further comprising a base substrate and a driver circuit and a light-emitting element located on one side of the base substrate, wherein the light-emitting element comprises a first light-emitting element and a second light-emitting element; and the driver circuit comprises a first driver circuit and a second driver circuit; and
a light-emitting pixel of the plurality of light-emitting pixels comprises the first light-emitting element and the first driver circuit electrically connected to the first light-emitting element, and a black pixel of the black pixels comprises the second light-emitting element and the second driver circuit electrically connected to the second light-emitting element.

19. The display panel of claim 18, wherein the second driver circuit receives a data signal corresponding to 0 grayscale; or, the second driver circuit is disposed in a manner of levitation; or, the first driver circuit and the second driver circuit are disposed independently.

20. A display device, comprising a display panel, wherein the display panel comprises a light-transmissive region, a display region at least partially surrounding the light-transmissive region, and a non-light-emitting region located between the light-transmissive region and the display region, wherein
in a radial direction of the light-transmissive region, a difference in a size of the non-light-emitting region located around the light-transmissive region is ΔD, wherein 0 μm≤|ΔD|≤10 μm.
